(19) United States
(12) Patent Application Publication
(10) Pub. No.: US 2024/0075496 A1
(43) Pub. Date: Mar. 7, 2024

(54) DEPOSITION APPARATUS

(71) Applicant: Samsung Display Co., LTD., Yongin-si (KR)

(72) Inventors: JONGYOON LEE, Yongin-si (KR); SOKWON NOH, Yongin-si (KR); SANG MIN YI, Yongin-si (KR)

(21) Appl. No.: 18/219,616

(22) Filed: Jul. 7, 2023

(30) Foreign Application Priority Data
Sep. 6, 2022 (KR) 10-2022-0112598

(51) Int. Cl. B05C 21/00; H10K 59/12

(52) U.S. Cl. CPC B05C 21/005; H10K 59/12

(57) ABSTRACT

A deposition apparatus includes a deposition member providing a deposition material, a stage including a first rear surface, a first front surface opposite to the first rear surface, and a first inner side surface extended to the first rear surface and the first front surface and defining a first opening, a mask frame including a second rear surface facing the first front surface, a second front surface opposite to the second rear surface, and a second inner side surface extended to the second front surface and the second rear surface and defining a second opening, masks disposed on the second front surface and each being provided with a plurality of deposition openings defined therethrough to correspond to the second opening, and a heat dissipation plate disposed between the deposition member and the stage and covering the first rear surface, the first inner side surface, and the second side inner surface.

This application claims priority to Korean Patent Application No. 10-2022-0112598, filed on Sep. 6, 2022, and all the benefits accruing therefrom under 35 U.S.C. § 119, the content of which in its entirety is herein incorporated by reference.

### BACKGROUND

### 1. Field

The disclosure relates to a deposition apparatus. More particularly, the disclosure relates to a deposition apparatus used to manufacture a display panel.

### 2. Description of the Related Art

Display devices, such as televisions, mobile phones, tablet computers, navigation devices, and game devices, include a display panel displaying an image. The display panel includes pixels. Each pixel includes a driving element, such as a transistor, and a display element, such as an organic light-emitting diode. The display element is formed by depositing an electrode and a light-emitting pattern on a substrate.

The light-emitting pattern is formed using a mask through which a deposition opening is defined. In recent years, a technology of a deposition process using a large-area mask is being developed to improve a production yield of a display panel.

### SUMMARY

However, when the mask is not placed at a desired position in a deposition apparatus, the light-emitting pattern is not formed exactly at the desired position.

The disclosure provides a deposition apparatus capable of performing a deposition process on a substantially large area and improving a deposition precision and reliability.

An embodiment of the inventive concept provides a deposition apparatus including a deposition member providing a deposition material, a stage including a first rear surface facing the deposition member, a first front surface opposite to the first rear surface, and a first inner side surface extended to the first rear surface and the first front surface, defining a first opening, and inclined with respect to each of the first front surface and the first rear surface, a mask frame including a second rear surface facing the first front surface, a second front surface opposite to the second rear surface, and a second inner side surface extended to the second front surface and the second rear surface, defining a second opening, and inclined with respect to each of the second front surface and the second rear surface, a plurality of masks disposed on the second front surface and each being provided with a plurality of deposition openings defined therethrough to correspond to the second opening, and a heat dissipation plate disposed between the deposition member and a mask of the plurality of masks and covering the first rear surface, the first inner side surface, and the second side inner surface.

In an embodiment, the heat dissipation plate includes a flat portion and an inclined portion bent from the flat portion, the flat portion covers the first rear surface, and the inclined portion covers the first inner side surface and the second inner side surface.

In an embodiment, the inclined portion is spaced apart from the second inner side surface.

In an embodiment, a distance between the inclined portion and the second inner side surface is equal to or greater than about 2 millimeter (mm) and equal to or smaller than about 10 mm.

In an embodiment, an angle between the inclined portion and the flat portion is equal to or greater than about 110 degrees and equal to or smaller than about 130 degrees.

In an embodiment, the inclined portion is spaced apart from the plurality of deposition openings in a plan view.

In an embodiment, the second inner side surface includes a first surface extending in a first direction, a second surface extending in the first direction and facing the first surface, a third surface extending in a second direction crossing the first direction and extended to the first surface and the second surface, and a fourth surface extending in the second direction and extended to the first surface and the second surface, and the inclined portion includes first, second, third, and fourth inclined surfaces respectively covering the first, second, third, and fourth surfaces, and each of the first, second, third, and fourth inclined surfaces includes one side extended to the flat portion and an opposite side opposing to the one side, and wherein the opposite sides of the first, second, third, and fourth inclined surfaces are able to be separated from each other.

In an embodiment, the first, second, third, and fourth inclined surfaces do not overlap each other.

In an embodiment, the heat dissipation plate further includes a cover member, at least a portion of the second inner side surface is exposed without being covered by the first, second, third, and fourth inclined surfaces, and the cover member covers the at least the portion of the second inner side surface.

In an embodiment, the first, second, third, and fourth inclined surfaces overlap each other in a plan view.

In an embodiment, the first inner side surface is aligned with the second inner side surface.

In an embodiment, the deposition apparatus further includes a support member coupled to the stage and supporting the heat dissipation plate.

In an embodiment, the stage further includes a groove defined in the first inner side surface, and the support member is inserted into the groove.

In an embodiment, at least a portion of the groove is spaced apart from the support member.

In an embodiment, the heat dissipation plate further includes a hole defined therethrough, and the support member is inserted into the hole.

In an embodiment, the support member includes a bolt.

In an embodiment, the support member includes at least one bending portion, and the bending portion supports a side surface of the heat dissipation plate.

An embodiment of the inventive concept provides a deposition apparatus further comprises a support member disposed on the heat dissipation plate and facing the first rear surface, and the heat dissipation plate is supported and coupled to the stage through the support member.

In an embodiment, one of the support member and the stage includes a concave portion defined therein, a remaining one of the support member and the support member includes a convex portion defined therein, and the convex portion is inserted into the concave portion.

In an embodiment, the support member protrudes to be inclined with respect to the first rear surface, and the support member is inserted into the stage.

In an embodiment, the first and second rear surfaces are substantially parallel to a gravity direction.

An embodiment of the inventive concept provides a deposition apparatus including a chamber including a bottom surface and a side surface to define an inner space, a deposition member disposed on the side surface to provide a deposition material, a mask frame accommodated in the inner space and including a rear surface facing the deposition member, a front surface opposite to the rear surface, a side surface extended to the front surface and the rear surface, and an inner side surface opposite to the side surface of the mask frame and defining an opening with a diameter that varies along a direction penetrating through the front surface and the rear surface, a plurality of masks disposed on the front surface and each being provided with a plurality of deposition openings defined therethrough to correspond to the opening, and a heat dissipation plate disposed between the deposition member and the mask frame and including a flat portion parallel to the rear surface and an inclined portion bent from the flat portion and covering the inner side surface.

In an embodiment, the inclined portion is parallel to the inner side surface and spaced apart from the inner side surface.

In an embodiment, the rear surface is inclined with respect to the bottom surface.

In an embodiment, the inclined portion has an integral shape.

In an embodiment, the inclined portion includes a plurality of inclined surfaces, and each of the plurality of inclined surfaces is extended to the flat portion and bent from the flat portion.

In an embodiment, angles between each of two of the inclined surfaces and the flat portion are different from each other.

In an embodiment, some of the inclined surfaces overlap each other in a plan view.

In an embodiment, the heat dissipation plate further includes a cover member, the inclined portion are spaced apart from each other in a plan view, and the cover member overlaps two inclined surfaces adjacent to each other among the inclined surfaces when viewed in the plan view.

According to the above, the mask frame is prevented from being thermally deformed due to a heat in a deposition process. Thus, a deposition precision is improved, and a process reliability is enhanced.

### BRIEF DESCRIPTION OF THE DRAWINGS

The above and other advantages of the disclosure will become readily apparent by reference to the following detailed description when considered in conjunction with the accompanying drawings wherein:

FIG. 1 is a cross-sectional view of an embodiment of a display panel according to the disclosure;

FIG. 2 is a cross-sectional view of an embodiment of a deposition apparatus according to the disclosure;

FIG. 3A is an exploded perspective view of an embodiment of a deposition apparatus according to the disclosure;

FIG. 3B is a plan view of an embodiment of a deposition apparatus according to the disclosure;

FIGS. 4A and 4B are cross-sectional views of an embodiment of a portion of a deposition apparatus according to the disclosure;

FIG. 5 is a cross-sectional view of an embodiment of a portion of a deposition apparatus according to the disclosure;

FIGS. 6A to 6C are cross-sectional views of an embodiment of a portion of deposition apparatuses according to the disclosure;

FIGS. 7A and 7B are cross-sectional views of an embodiment of a portion of deposition apparatuses according to the disclosure;

FIG. 8 is a plan view of an embodiment of a deposition apparatus according to the disclosure;

FIG. 9A is a plan view of an embodiment of a deposition apparatus according to the disclosure;

FIGS. 9B to 9D are views of an embodiment of portions taken along line X-X′ shown in FIG. 9A;

FIG. 10A is a plan view of an embodiment of a deposition apparatus according to the disclosure;

FIGS. 10B and 10C are cross-sectional views of an embodiment of a portion of deposition apparatuses according to the disclosure;

FIG. 11A is a plan view of a deposition apparatus according to the disclosure;

FIG. 11B is a cross-sectional view of an embodiment of a portion of a deposition apparatus according to the disclosure; and

FIGS. 12A and 12B are enlarged cross-sectional views of an area KK shown in FIG. 11B.

### DETAILED DESCRIPTION

In the disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content.

As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” or the like, may be used herein for ease of description to describe one element or feature's relationship to another elements or features as shown in the drawing figures.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Hereinafter, embodiments of the disclosure will be described with reference to accompanying drawings.

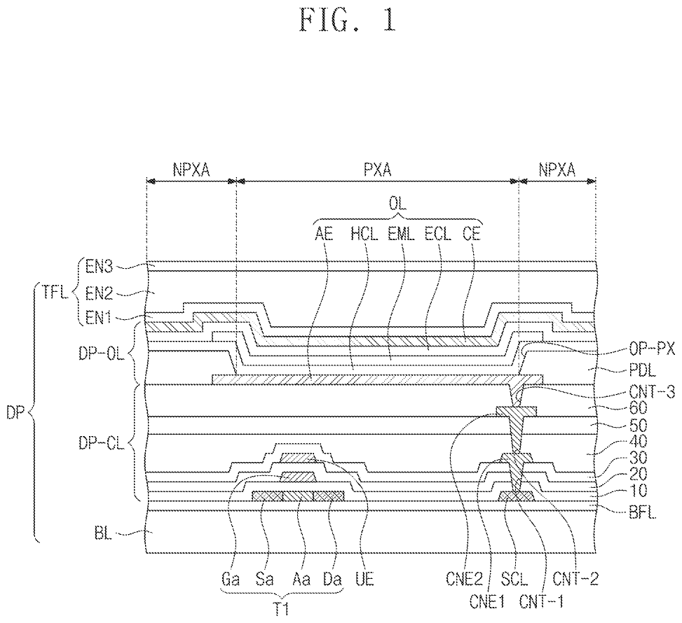

FIG. 1 is a cross-sectional view of an embodiment of a display panel DP according to the disclosure.

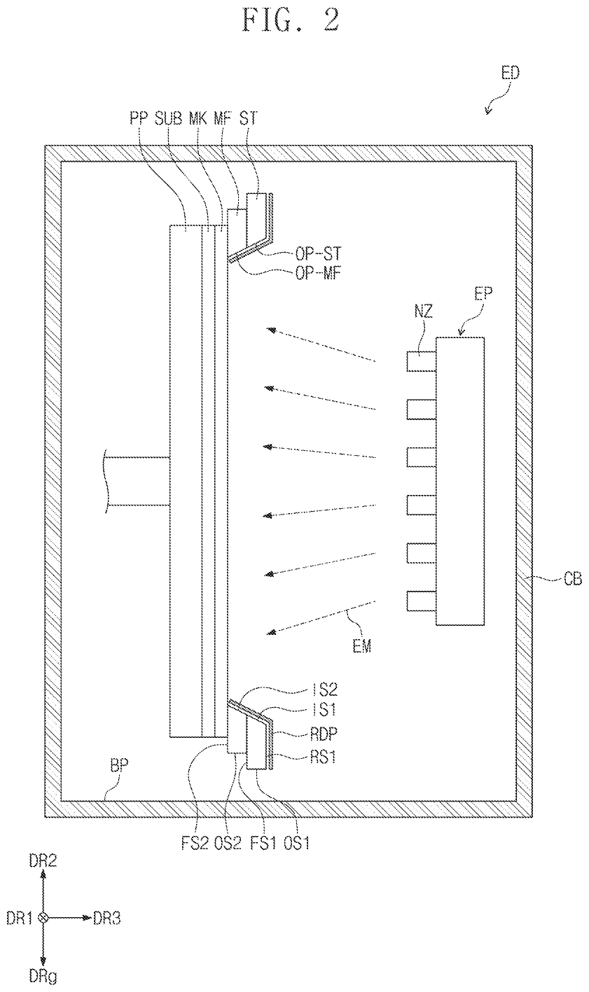

A deposition apparatus ED (refer to FIG. 2) described later may be used to form at least one of functional layers included in the display panel DP. FIG. 1 shows a cross-section of the display panel DP manufactured using the deposition apparatus ED (refer to FIG. 2).

In an embodiment, the display panel DP may be a light-emitting type display panel. In an embodiment, the display panel DP may be an organic light-emitting display panel, an inorganic light-emitting display panel, or a quantum dot light-emitting display panel. A light-emitting layer of the organic light-emitting display panel may include an organic light-emitting material. A light-emitting layer of the inorganic light-emitting display panel may include an inorganic light-emitting material. A light-emitting layer of the quantum dot light-emitting display panel may include a quantum dot or a quantum rod. Hereinafter, the organic light-emitting display panel will be described as an illustrative embodiment of the display panel DP.

The display panel DP may include a plurality of pixels. Each of the pixels may include at least one transistor and a light-emitting element. FIG. 1 shows one transistor T1 and a light-emitting element OL, which are included in one pixel of the display panel DP. Referring to FIG. 1, the display panel DP may include a base layer BL, a circuit element layer DP-CL, a display element layer DP-OL, and an encapsulation layer TFL.

The base layer BL may provide a base surface on which the circuit element layer DP-CL is disposed. The base layer BL may include a synthetic resin layer. The synthetic resin layer may be formed or disposed on a support substrate used when the display panel DP is manufactured, and a conductive layer and an insulating layer may be formed or disposed on the synthetic resin layer. Then, the support substrate may be removed, and the synthetic resin layer from which the support substrate is removed may correspond to the base layer BL.

At least one inorganic layer may be disposed on the base layer BL. The inorganic layer may form a barrier layer and/or a buffer layer. FIG. 1 shows the buffer layer BFL disposed on the base layer BL as an illustrative embodiment. The buffer layer BFL may increase an adhesion between the base layer BL and a semiconductor pattern of the circuit element layer DP-CL.

The circuit element layer DP-CL may be disposed on the buffer layer BFL. The circuit element layer DP-CL may include at least one insulating layer and a circuit element. The circuit element may include a signal line and a driving circuit of the pixel. An insulating layer, a semiconductor layer, and a conductive layer may be formed by a coating or depositing process, and the insulating layer, the semiconductor layer, and the conductive layer may be patterned through several photolithography processes. Thus, the circuit element layer DP-CL may be formed.

In the illustrated embodiment, the circuit element layer DP-CL may include the transistor T1, a connection signal line SCL, connection electrodes CNE1 and CNE2, and a plurality of insulating layers 10 to 60. The insulating layers 10 to 60 may include first, second, third, fourth, fifth, and sixth insulating layers 10, 20, 30, 40, 50, and 60, which are sequentially stacked on the buffer layer BFL. Each of the first to sixth insulating layers 10 to 60 may include at least one of an inorganic layer and an organic layer.

The transistor T1 may include the semiconductor pattern including a source area Sa, an active area Aa, and a drain area Da and a gate electrode Ga. The semiconductor pattern of the transistor T1 may include polycrystalline silicon, however, it should not be limited thereto or thereby. In an embodiment, the semiconductor pattern may include amorphous silicon or metal oxide. In another embodiment, the source area Sa may be a drain area and the drain area Da may be source area based on a type of the transistor T1.

The semiconductor pattern may include a plurality of areas distinguished from each other depending on its conductivity. In an embodiment, the semiconductor pattern may have different electrical properties depending on whether it is doped or not or whether the metal oxide is reduced or not. An area of the semiconductor pattern, which has a relatively large conductivity, may substantially act as an electrode or a signal line and may correspond to the source area Sa and the drain area Da of the transistor T1. An area of the semiconductor pattern, which is not doped or not reduced and has a relatively small conductivity, may substantially correspond to the active area (or a channel area) Aa of the transistor T1.

The connection signal line SCL may be formed from the semiconductor pattern, and the connection signal line SCL, the source area Sa, the active area Aa, and the drain area Da of the transistor T1 may be disposed in the same layer. In an embodiment, the connection signal line SCL may also be electrically connected to the drain area Da of the transistor T1 in a plane.

The first insulating layer 10 may cover the semiconductor pattern of the circuit element layer DP-CL. The gate electrode Ga may be disposed on the first insulating layer 10. The gate electrode Ga may overlap the active area Aa. The gate electrode Ga may serve as a mask in a process of doping the semiconductor pattern. An upper electrode UE may be disposed on the second insulating layer 20. The upper electrode UE may overlap the gate electrode Ga.

A first connection electrode CNE1 and a second connection electrode CNE2 may be disposed between the transistor T1 and the light-emitting element OL and may electrically connect the transistor T1 to the light-emitting element OL. The first connection electrode CNE1 may be disposed on the third insulating layer 30 and may be connected to the connection signal line SCL via a contact hole CNT-1 defined through the first to third insulating layers 10 to 30. The second connection electrode CNE2 may be disposed on the fifth insulating layer 50 and may be connected to the first connection electrode CNE1 via a contact hole CNT-2 defined through the fourth and fifth insulating layers 40 and 50.

The display element layer DP-OL may be disposed on the circuit element layer DP-CL. The display element layer DP-OL may include the light-emitting element OL and a pixel definition layer PDL. The light-emitting element OL may include a first electrode AE, a hole control layer HCL, a light-emitting layer EML, an electron control layer ECL, and a second electrode CE.

The first electrode AE and the pixel definition layer PDL may be disposed on the sixth insulating layer 60. The first electrode AE may be connected to the second connection electrode CNE2 via a contact hole CNT-3 defined through the sixth insulating layer 60. The pixel definition layer PDL may be provided with a light-emitting opening OP-PX defined therethrough to expose at least a portion of the first electrode AE, and the portion of the first electrode AE exposed through the light-emitting opening OP-PX may correspond to a light-emitting area PXA. A non-light-emitting area NPXA may surround the light-emitting area PXA.

The hole control layer HCL and the electron control layer ECL may be commonly disposed over the light-emitting area PXA and the non-light-emitting area NPXA. The light-emitting layer EML may be patterned to correspond to the light-emitting opening OP-PX. The patterned light-emitting layer EML may be formed using the deposition apparatus ED (refer to FIG. 2) according to the disclosure.

When compared with the hole control layer HCL and the electron control layer ECL each being provided in the form of a film, the light-emitting layer EML may be deposited in different ways. The hole control layer HCL and the electron control layer ECL may be commonly formed in the pixels using an open mask. The light-emitting layer EML may be formed differently according to the pixels using a mask referred to as a fine metal mask (“FMM”).

The encapsulation layer TFL may include a plurality of thin layers. The encapsulation layer TFL may include first, second, and third thin layers EN1, EN2, and EN3 sequentially stacked. Each of first, second, and third thin layers EN1, EN2, and EN3 may include one of an inorganic layer and an organic layer. The inorganic layer may protect the light-emitting element OL from moisture and/or oxygen. The organic layer may protect the light-emitting element OL from a foreign substance such as dust particles. However, the configuration of the encapsulation layer TFL should not be limited to the illustrated components as long as the light-emitting element OL is protected or a light-emitting efficiency is improved.

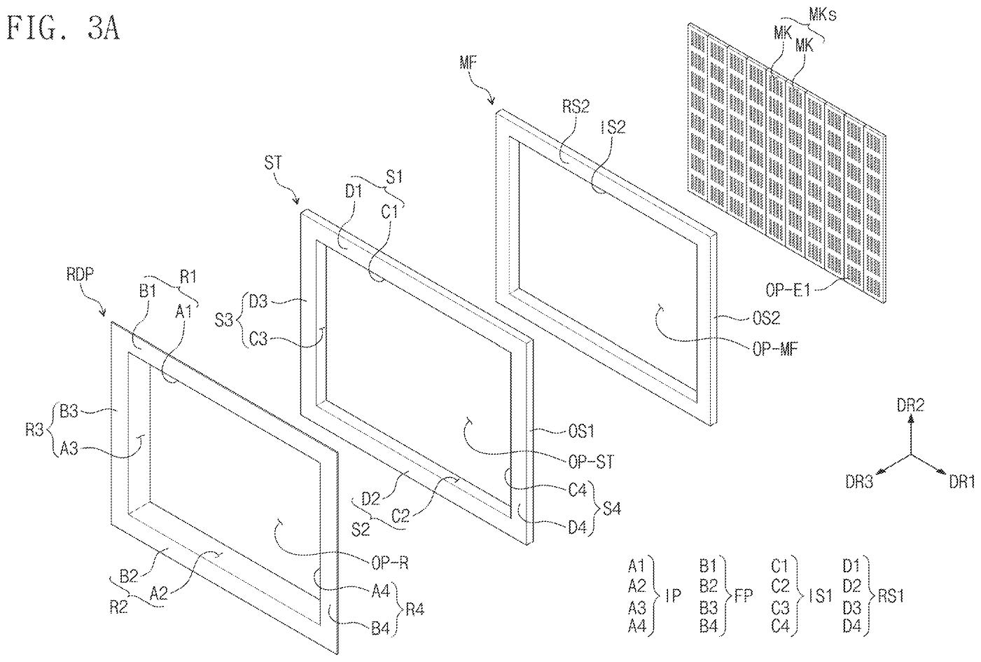

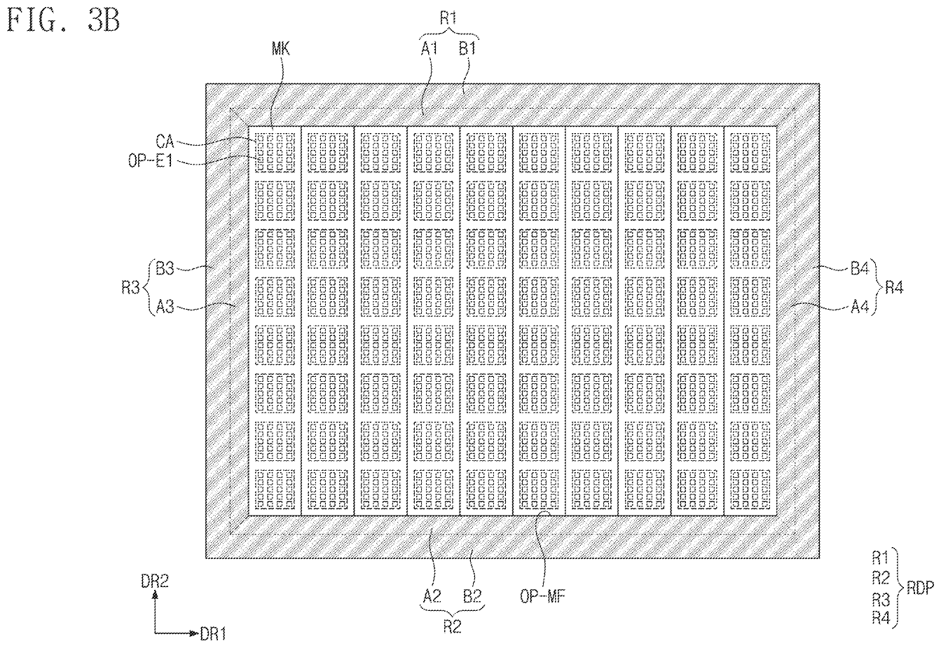

FIG. 2 is a cross-sectional view of an embodiment of the deposition apparatus ED according to the disclosure. FIG. 3A is an exploded perspective view of an embodiment of the deposition apparatus according to the disclosure. FIG. 3B is a plan view of an embodiment of the deposition apparatus according to the disclosure. FIG. 3B is a plan view showing an assembled state of components shown in FIG. 3A when viewed in a direction toward a rear surface RS1 of a stage ST. Hereinafter, the disclosure will be described with reference to FIGS. 2, 3A, and 3B.

Referring to FIG. 2, the deposition apparatus ED may include a chamber CB, a deposition member EP, a fixing member PP, a mask MK, a mask frame MF, the stage ST, and a heat dissipation plate RDP. The deposition apparatus ED may further include additional mechanisms to implement an inline system.

The chamber CB may define an inner space therein, and the deposition member EP, the fixing member PP, the mask MK, the mask frame MF, the stage ST, and the heat dissipation plate RDP may be disposed in the inner space of the chamber CB. The chamber CB may form an enclosed space, and a deposition condition of the chamber CB may be set to a vacuum state. The chamber CB may include at least one gate and may be opened or closed by the gate. The mask MK, the mask frame MF, and a substrate SUB may enter and exit through the gate provided to the chamber CB.

The chamber CB may include a bottom surface BP, a ceiling surface, and sidewalls. The bottom surface BP, the ceiling surface, and the sidewalls may form the chamber CB in a box shape. The bottom surface BP of the chamber CB may be substantially parallel to a plane defined by a first direction DR1 and a third direction DR3, and a normal line direction of the bottom surface BP of the chamber CB may be substantially parallel to a second direction DR2. In the expression “in a plan view” used in the disclosure, the plan view may be a view of a plane defined by the first direction DR1 and the second direction DR2 from above.

The fixing member PP may be disposed facing the deposition member EP in the chamber CB. The fixing member PP may fix the substrate SUB onto the mask MK. The fixing member PP may include a jig or a robot arm to hold the mask MK. The fixing member PP may include magnetic substances to tightly adhere the substrate SUB to the mask MK. In an embodiment, the magnetic substances may generate a magnetic force to fix the mask MK, and the substrate SUB disposed between the mask MK and the fixing member PP may be tightly adhered to the mask MK.

The substrate SUB may be a process target on which a deposition material is deposited. In an embodiment, the substrate SUB may include a support substrate and a synthetic resin layer disposed on the support substrate. The support substrate may be removed in a later process of a manufacturing process of the display panel, and the synthetic resin layer may correspond to the base layer BL (refer to FIG. 1). The substrate SUB may include some components of the display panel DP (refer to FIG. 1) formed or disposed on the base layer BL (refer to FIG. 1) depending on components to be formed through the deposition process.

The deposition member EP may be disposed in the chamber CB to face the fixing member PP. The deposition member EP may include a space to accommodate the deposition material and at least one nozzle NZ. The deposition material EM may include an inorganic material, a metal material, or an organic material that is sublimable or vaporable. In an embodiment, the deposition material EM may include an organic light-emitting material to form the light-emitting layer EML, however, the deposition material EM should not be limited thereto or thereby. The sublimed or vaporized deposition material EM may be sprayed to the substrate SUB through the nozzle NZ. The deposition material EM may be deposited on the substrate SUB in a predetermined pattern after passing through the mask MK.

The stage ST may be disposed between the deposition member EP and the fixing member PP. The stage ST may include a rear surface RS1 (hereinafter, also referred to as a first rear surface), a front surface FS1 (hereinafter, also referred to as a first front surface), an outer side surface OS1 (hereinafter, also referred to as a first outer side surface), and an inner side surface IS1 (hereinafter, also referred to as a first inner side surface). The first front surface FS1 may face the mask frame MF. The first rear surface RS1 may be opposite to the first front surface FS1. The first rear surface RS1 may face the deposition member EP. Each of the first front surface FS1 and the first rear surface RS1 may be substantially parallel to the plane defined by the first direction DR1 and the second direction DR2.

The second direction DR2 may be opposite to a gravity direction DRg. The second direction DR2 may be parallel or substantially parallel to the gravity direction DRg, and only a vector value of the second direction DR2 may be opposite to that of the gravity direction DRg. In the illustrated embodiment, the gravity direction DRg may be perpendicular to the bottom surface BP.

The first front surface FS1 of the stage ST may be substantially perpendicular to the bottom surface BP of the chamber CB. Accordingly, the rear surface of each of the mask frame MF and the mask MK disposed on the first front surface FS1 of the stage ST may be provided to be substantially perpendicular to the bottom surface BP of the chamber CB, and then the deposition process may be performed. Accordingly, the mask MK with substantially large size may be prevented from sagging by gravity, and thus, a deposition reliability may be improved.

However, in an embodiment, the first front surface FS1 of the stage ST may be provided to be substantially parallel to the bottom surface BP of the chamber CB, the rear surface of each of the mask frame MF and the mask MK may be provided to be substantially parallel to the bottom surface BP of the chamber CB, and then the deposition process may be performed.

The first outer side surface OS1 may extend to or from the first front surface FS1 and the first rear surface RS1. The first outer side surface OS1 may define a side surface of the stage ST. The first inner side surface IS1 may extend to or from the first front surface FS1 and the first rear surface RS1 and may be opposite to the first outer side surface OS1. The first inner side surface IS1 may define a first opening OP-ST.

In the illustrated embodiment, the first inner side surface IS1 of the stage ST may be inclined with respect to the first front surface FS1 or the first rear surface RS1. A minimum angle between the first inner side surface IS1 and the first front surface FS1 extended to or from the first inner side surface IS1 may be smaller than about 90 degrees, and a minimum angle between the first inner side surface IS1 and the first rear surface RS1 extended to or from the first inner side surface IS1 may be greater than about 90 degrees and smaller than about 180 degrees. Accordingly, the first opening OP-ST defined through the stage ST may have an inner diameter that decreases as a distance from the deposition member EP increases in a direction substantially parallel to the third direction DR3.

The mask frame MF may be coupled with the mask MK and may support the mask MK. The mask frame MF may include a plurality of portions that defines an opening OP-MF (hereinafter, also referred to as a second opening) overlapping deposition openings of the mask MF. That is, the mask frame MF may have a frame shape surrounding the second opening OP-MF in the plan view. This structure will be described in detail later.

The mask frame MF may include a rear surface RS2 (hereinafter, also referred to as a second rear surface), a front surface FS2 (hereinafter, also referred to as a second front surface), an outer side surface OS2 (hereinafter, also referred to as a second outer side surface), and an inner side surface IS2 (hereinafter, also referred to as a second inner side surface). The second front surface FS2 may face the mask MK and may be coupled with the mask MK. The second rear surface RS2 may be opposite to the second front surface FS2. The second rear surface RS2 may face the stage ST and may face the deposition member EP. Each of the second front surface FS2 and the second rear surface RS2 of the mask frame MF may be substantially parallel to the first direction DR1 and the second direction DR2.

The second outer side surface OS2 may extend to or from the second front surface FS2 and the second rear surface RS2. The second outer side surface OS2 may define a side surface of the mask frame MF. The second inner side surface IS2 may extend to or from the second front surface FS2 and the second rear surface RS2 and may be opposite to the second outer side surface OS2. The second inner side surface IS2 may extend to or from the second front surface FS2 and the second rear surface RS2 and may define the second opening OP-MF. The second opening OP-MF may overlap the first opening OP-ST in a plan view facing the plane defined by the first direction DR1 and the second direction DR2.

In the illustrated embodiment, the second inner side surface IS2 of the mask frame MF may be inclined with respect to the second front surface FS2 or the second rear surface RS2. A minimum angle between the second inner side surface IS2 and the second front surface FS2 extended to or from the second inner side surface IS2 may be smaller than about 90 degrees, and a minimum angle between the second inner side surface IS2 and the second rear surface RS2 extended to or from the second inner side surface IS2 may be greater than about 90 degrees and smaller than about 180 degrees. Accordingly, the second opening OP-MF defined through the mask frame MF may have an inner diameter that decreases as a distance from the deposition member EP in the third direction DR3 increases.

The mask MK may include the deposition openings that define a deposition area. The mask MK may be placed to allow the deposition openings to overlap the first opening OP-ST and the second opening OP-MF. The mask MK may be disposed on the second front surface FS2 of the mask frame MF and may be supported by the second front surface FS2.

The heat dissipation plate RDP may be disposed between the stage ST and the deposition member EP. The heat dissipation plate RDP may cover the stage ST and the inner side surfaces IS1 and IS2 of the mask frame MF. In detail, the heat dissipation plate RDP may include flat portion FP and inclined portion IP.

The flat portion FP may cover the first rear surface RS1 of the stage ST so as not to be exposed to the deposition member EP. The flat portion FP may be substantially parallel to the first rear surface RS1. That is, the flat portion FP may be substantially parallel to the plane defined by the first direction DR1 and the second direction DR2. The flat portion FP may prevent the first rear surface RS1 from being exposed to the deposition member EP.

The inclined surfaces A1 to A4 may be extended to or from the flat portion FP and may be bent from the flat portion FP. That is, the inclined portion IP may be inclined with respect to the flat portion FP. The inclined portion IP may be substantially parallel to each of the first inner side surface IS1 and the second inner side surface IS2. The inclined portion IP may cover the first inner side surface IS1 and the second inner side surface IS2. The inclined portion IP may prevent the first inner side surface IS1 and the second inner side surface IS2 from being exposed to the deposition member EP.

The heat dissipation plate RDP may include a material with relatively high heat conductivity. In an embodiment, the heat dissipation plate RDP may include a metal material, such as aluminum or copper, an alloy thereof, carbon, graphite, or any combinations thereof. The heat dissipation plate RDP may absorb the heat dissipated from the deposition member EP. Accordingly, the heat dissipated from the deposition member EP may be prevented from being transmitted to the stage ST or the mask frame MF, and thus, the mask frame MF may be prevented from being deformed due to the heat. The heat dissipation plate RDP may further include a heat blocking layer. The heat blocking layer may reflect or block the heat.

In the illustrated embodiment, as the heat dissipation plate RDP is disposed between the deposition member EP and the mask frame MF, the mask frame MF, particularly, the second inner side surface IS2 may be prevented from being exposed to the heat dissipated from the deposition member EP. Since the heat dissipation plate RDP may further include the inclined portion IP, the heat dissipation plate RDP may cover not only the first rear surface RS1 of the stage ST but also the first inner side surface IS1 and the second inner side surface IS2. Accordingly, the deformation of the mask frame MF, which is caused by the heat, may be prevented, and it is possible to prevent a defect in deposition from occurring in the deposition process. Accordingly, a reliability and precision of the deposition process may be improved.

The heat dissipation plate RDP may be embodied in various ways as long as the heat dissipation plate RDP prevents the heat from the deposition member EP from affecting the mask frame MF and should not be particularly limited.

Referring to FIGS. 3A and 3B, the stage ST may have a quadrangular (e.g., rectangular) closed line shape in the plan view. The stage ST may include a plurality of sides S1, S2, S3, and S4 that defines the first opening OP-ST. The sides S1, S2, S3, and S4 may be integrally provided with each other to surround the first opening OP-ST and may form a single stage ST. Each of first and second sides S1 and S2 may extend in the first direction DR1, and each of third and fourth sides S3 and S4 may extend in the second direction DR2.

The sides S1, S2, S3, and S4 may respectively include flat surfaces D1, D2, D3, and D4 defining the first rear surface RS1, and may respectively include inclined surfaces C1, C2, C3, and C4 defining the first inner side surface IS1. The first rear surface RS1 of the stage ST shown in FIG. 2 may be one of the flat surfaces D1, D2, D3, and D4, and the first inner side surface IS1 of the stage ST shown in FIG. 2 may be one of the inclined surfaces C1, C2, C3, and C4.

As described above, the first opening OP-ST may have the inner diameter varying along a thickness direction of the stage ST. The thickness direction may be a direction passing through the first rear surface RS1 and the first front surface and substantially parallel to the third direction DR3. In detail, the first opening OP-ST may have a size increasing as a distance from the first rear surface RS1 decreases and decreasing as a distance from the first front surface FS1 decreases. The inner diameter of the first opening OP-ST may be changed depending on an inclination of the first inner side surface RS1.

As described above, the mask frame MF may include the second front surface (not shown) facing the mask MK, the second rear surface RS2 opposite to the second front surface, the second inner side surface IS2 defining the second opening OP-MF, and the second outer side surface OS2 defining the side surface. In the illustrated embodiment, the mask frame MF may have an integral shape. The mask frame MF may have a quadrangular (e.g., rectangular) closed line shape in the plan view. That is, each of the second front surface FS2, the second rear surface RS2, the second inner side surface IS2, and the second outer side surface OS2 may include two surfaces extending in the first direction DR1 and two surfaces extending in the second direction DR2. In an embodiment, four surfaces defining the second rear surface RS2 are respectively corresponding to the flat surfaces D1, D2, D3, and D4 defining the first rear surface RS1, for example. Four surfaces defining the second inner side surface IS2 are respectively corresponding to the inclined surfaces C1, C2, C3, and C4 defining the first inner side surface IS1.

The second opening OP-MF may have the inner diameter varying along a thickness direction of the mask frame MF. In detail, the second opening OP-MF may have a size increasing as a distance from the second rear surface RS2 decreases and decreasing as a distance from the second front surface FS2 decreases. The inner diameter of the second opening OP-MF may be changed depending on an inclination of the second inner side surface IS2.

The masks MKs may be disposed on the rear surface of the mask frame MF and may be coupled with the rear surface by welding. Each mask MK may be provided with a plurality of deposition openings OP-E1 overlapping the first opening OP-ST in cell areas CA, and the second opening OP-MF.

The heat dissipation plate RDP may have a quadrangular (e.g., rectangular) closed line shape in the plan view. The shape of the heat dissipation plate RDP may correspond to the mask frame MF and the stage ST. That is, the heat dissipation plate RDP may include a plurality of portions R1, R2, R3, and R4 defining an opening OP-R. The portions R1, R2, R3, and R4 may be integrally provided with each other to surround the opening OP-R and may form a single heat dissipation plate RDP. The portions R1, R2, R3, and R4 may include first, second, third, and fourth portions R1, R2, R3, and R4. The first and second portions R1 and R2 may extend in the first direction DR1, and the third and fourth portions R3 and R4 may extend in the second direction DR2.

The first, second, third, and fourth portions R1, R2, R3, and R4 may respectively correspond to and may respectively cover the four sides S1, S2, S3, and S4 of the stage ST. The first, second, third, and fourth portions R1, R2, R3, and R4 may respectively include flat surfaces B1, B2, B3, and B4 defining the flat portion FP and may respectively include inclined surfaces A1, A2, A3, and A4 defining the inclined portion IP. The flat surfaces B1, B2, B3, and B4 may respectively cover the flat surfaces D1, D2, D3, and D4 of the stage ST. The inclined surfaces A1, A2, A3, and A4 may respectively cover the inclined surfaces C1, C2, C3, and C4 of the stage ST. In the illustrated embodiment, the inclined surfaces A1, A2, A3, and A4 may extend to cover the second inner side surface IS2 of the mask frame MF.

FIG. 3B shows an assembled structure of the components RDP, ST, MF, and MKs shown in FIG. 3A when viewed from the deposition member EP (refer to FIG. 2). Referring to FIG. 3B, when viewed from the deposition member EP (refer to FIG. 2), the masks MK may be exposed without being covered by the heat dissipation plate RDP, and the mask frame MF or the stage ST may be covered by the heat dissipation plate RDP. As the first, second, third, and fourth portions R1, R2, R3, and R4 of the heat dissipation plate RDP respectively include the inclined surfaces A1, A2, A3, and A4 defining the inclined portion IP and respectively include the flat surfaces B1, B2, B3, and B4 defining the flat portions, the heat dissipation plate RDP may stably cover remaining portions, such as the mask frame MF or the stage ST, other than the deposition openings OP-E1, which are the areas desired for deposition. Accordingly, the stage ST or the mask frame MF may be prevented from being thermally deformed due to the heat dissipated from the deposition member EP. Thus, the mask frame MF may be prevented from being damaged during the deposition process, and deposition precision and reliability may be improved.

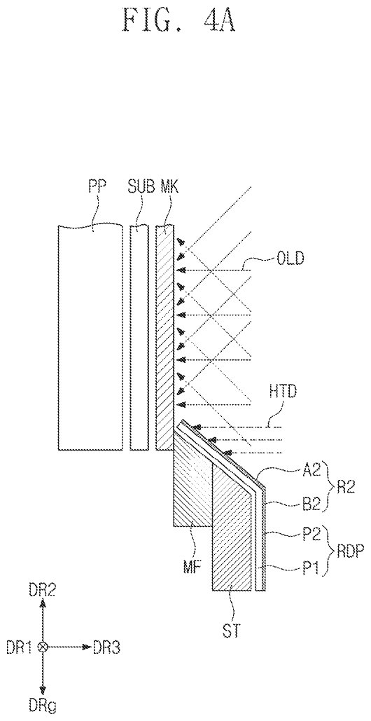

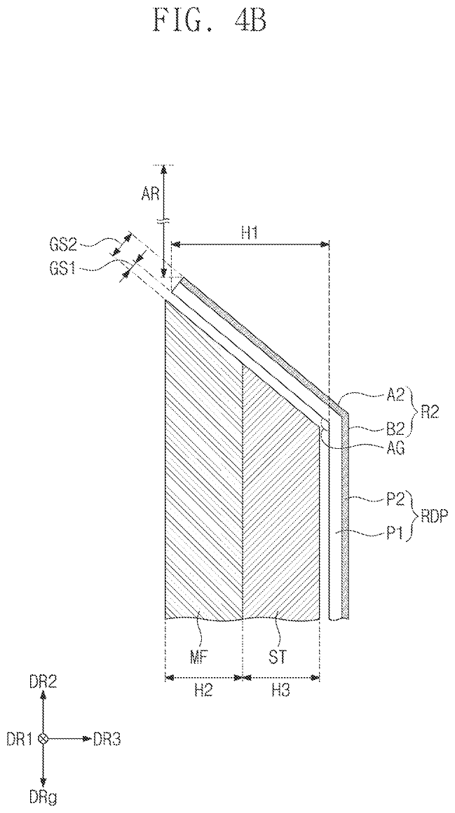

FIGS. 4A and 4B are cross-sectional views of an embodiment of a portion of the deposition apparatus according to the disclosure. For the convenience of explanation, some components are omitted in FIG. 4B. FIGS. 4A and 4B are enlarged cross-sectional views of an area where the second portion of the heat dissipation plate RDP is disposed. FIGS. 4A and 4B show the inclined surface A2 of the second portion R2 of the inclined portion IP (refer to FIG. 3a) and the flat surface B2 of the second portion R2 of the flat portion FP (refer to FIG. 3a) as an illustrative embodiment. Therefore, hereinafter, the inclined surface A2 of the second portion R2 may refer as the inclined portion and the flat surface B2 of the second portion R2 may refer as the flat portion. In FIGS. 4A and 4B, the same reference numerals denote the same elements in FIGS. 1, 2, 3A, and 3B, and thus, detailed descriptions of the same elements will be omitted.

For the convenience of explanation, FIG. 4A schematically shows a deposition path OLD and a heat transmission path HTD of an organic material sprayed from the deposition member EP (refer to FIG. 2). As shown in FIG. 4A, the deposition path OLD of the organic material may be formed in various directions and may travel to the mask MK, and thus, the organic material may be deposited on the substrate SUB. The heat transmission path HTD may have a relative linearity compared with the deposition path OLD of the organic material. The heat transmission path HTD may travel to the heat dissipation plate RDP from the deposition member EP. Although not shown in drawing figures, a portion of the deposition path OLD of the organic material may correspond to the heat transmission path HTD. In addition, a portion of the heat transmission path HTD may correspond to the deposition path OLD of the organic material.

In this case, the heat traveling along the heat transmission path HTD may be blocked by the heat dissipation plate RDP and thus may not reach the mask frame MF or the stage ST. As the heat dissipation plate RDP includes the flat portion B2 and the inclined portion A2, the inner side surfaces and the rear surfaces of the stage ST and the mask frame MF may be covered by the heat dissipation plate RDP. Accordingly, the thermal deformation of the mask frame MF, which is caused by the heat dissipated from the deposition member EP, may be easily prevented.

Referring to FIG. 4B, an effective area AR, which desires the deposition by the organic material, may be exposed from an end of the inclined portion A2 of the heat dissipation plate RDP. That is, the effective area AR may be an area where the deposition path OLD of the organic material reaches and may not overlap the heat dissipation plate RDP in the plan view.

In the illustrated embodiment, the heat dissipation plate RDP may be spaced apart from the mask frame MF or the stage ST by a predetermined distance (also referred to as a separation distance) GS1. In a case where the heat dissipation plate RDP contacts the mask frame MF without the separation distance GS1, the heat absorbed by the heat dissipation plate RDP may be transmitted to the mask frame MF, and the mask frame MF may be thermally deformed.

A maximum distance GS2 defined by a sum of a thickness of the heat dissipation plate RDP and the separation distance GS1 may be about 6 millimeter (mm)±4 mm when the thickness of the heat dissipation plate RDP is about 2 mm. That is, in a case where the separation distance GS1 between the inner side surface of the mask frame MF and the inclined portion A2 of the heat dissipation plate RDP is smaller than about 2 mm, the heat absorbed by the heat dissipation plate RDP may be transmitted to the mask frame MF, and the mask frame MF may be thermally deformed. In addition, in a case where the maximum distance GS2 is greater than about 10 mm, the deposition path OLD of the organic material may be blocked by the heat dissipation plate RDP, and a size of the effective area AR may be reduced. The distances GS1 and GS2 between the heat dissipation plate RDP and the mask frame MF may be designed with various values as long as it does not affect thermal blocking properties and securing the minimum size of the effective area AR.

An inclination angle AG of the heat dissipation plate RDP may be a minimum inclination angle defined between the flat portion B2 and the inclined portion A2. When the inclination angle of the second inner side surface of the mask frame MF with respect to the second rear surface is about 120 degrees, the inclination angle AG may be about 120±10 degrees. That is, the inclination angle AG may be within a range equal to or greater than about 110 degrees and equal to or smaller than about 130 degrees. The inclination angle AG may be an angle in a range that allows the inclined portion A2 to be substantially parallel to each of the first inner side surface and the second inner side surface and may be set in consideration of a tolerance range and a degree of sagging due to gravity. When the inclination angle AG is significantly different from the inclination angle of the mask frame MF, the inclined portion A2 may contact the mask frame MF or may invade the effective area AR.

In the illustrated embodiment, a height H1 of the inclined portion A2 may correspond to a value obtained by adding the separation distance GS1 to a sum of a thickness H2 of the mask frame MF and a thickness H3 of the stage ST, however, this is merely one of embodiments. In an embodiment, the height H1 of the inclined portion A2 may be designed to have various values as long as the inclined portion A2 does not invade the effective area AR and is spaced apart from the mask frame MF or the stage ST by the predetermined distance and should not be particularly limited.

The heat dissipation plate RDP may include a first layer P1 and a second layer P2. The first layer P1 may include a material with a relatively high thermal conductivity. The second layer P2 may have a reflectance higher than that of the first layer P1. In an embodiment, the second layer P2 may be a surface obtained by mirror-treating the first layer P1. In an embodiment, the second layer P2 may be a coating layer formed or disposed on a surface of the first layer P1. In the illustrated embodiment, as the heat dissipation plate RDP includes the second layer P2, an emissivity of the heat dissipation plate RDP may be reduced with comparing an emissivity of a plate including or consisting of the first layer P1. In addition, the second layer P2 may be formed only in the inclined portion A2 without being formed in the flat portion B2. The heat dissipation plate RDP may include various embodiments and should not be particularly limited.

In the illustrated embodiment, since the inclination angle AG of the heat dissipation plate RDP or the distances GS1 and GS2 from the mask frame MF are adjusted, the thermal deformation of the mask frame MF may be easily prevented, and the effective area AR may be sufficiently secured. Accordingly, the reliability and precision of the deposition process may be improved.

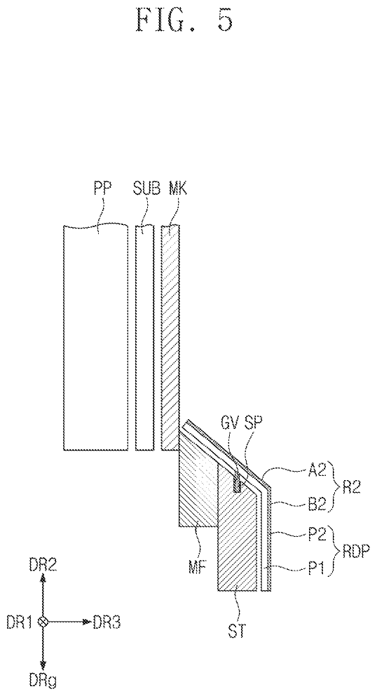

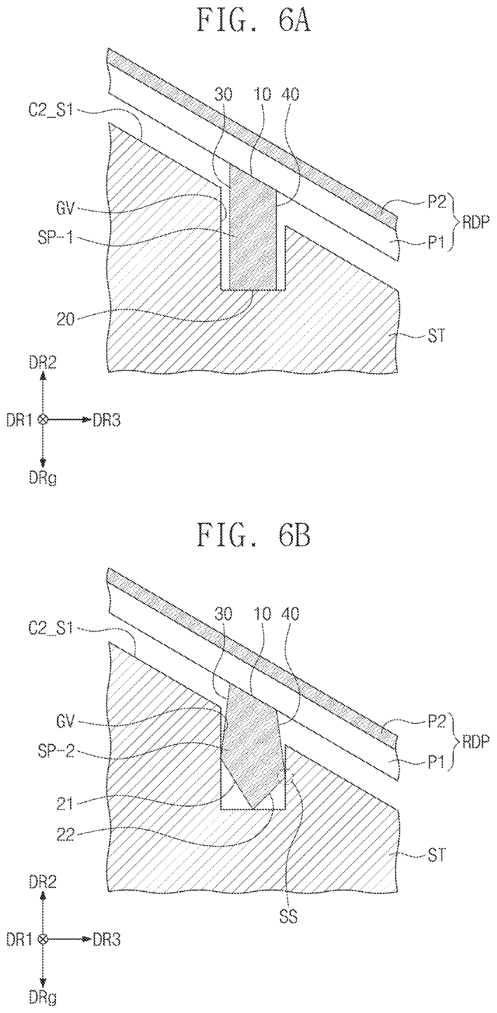

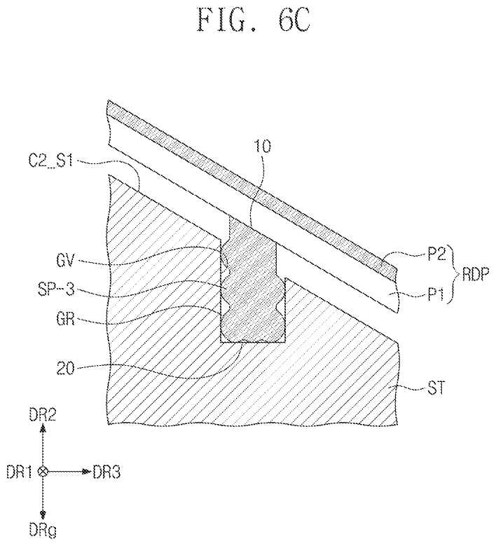

FIG. 5 is a cross-sectional view of an embodiment of a portion of a deposition apparatus according to the disclosure. FIGS. 6A to 6C are cross-sectional views of an embodiment of a portion of deposition apparatuses according to the disclosure. FIGS. 6A to 6C are enlarged views of a portion of the deposition apparatus shown in FIG. 5. In FIGS. 5 and 6A to 6C, the same reference numerals denote the same elements in FIGS. 1 to 4B, and thus, detailed descriptions of the same elements will be omitted.

Referring to FIG. 5, the deposition apparatus may further include a support member SP. The support member SP may contact a heat dissipation plate RDP and may substantially support the heat dissipation plate RDP. The support member SP may be inserted into a groove GV defined in a stage ST. The support member SP may maintain a distance GS1 (refer to FIG. 4B) between the heat dissipation plate RDP and the stage ST while supporting the heat dissipation plate RDP.

In detail, as shown in FIG. 6A, a support member SP-1 may include a support surface 10, a lower surface 20, and side surfaces 30 and 40. The support surface 10 may contact a heat dissipation plate RDP and may support the heat dissipation plate RDP. Accordingly, the support surface 10 may be an inclined surface corresponding to an inner side surface C2_S1 of a stage ST.

The lower surface 20 may contact a surface of a groove GV. Although not shown in drawing figures, the lower surface 20 may be coupled with the groove GV by a separate coupling member such as an adhesive member. The side surfaces 30 and 40 may be spaced apart from the groove GV. In the illustrated embodiment, as at least a portion of the surface of the groove GV is spaced apart from the support member SP-1, a contact area between the support member SP-1 and the groove GV may be reduced. Accordingly, a heat absorbed by the heat dissipation plate RDP may be prevented from being transmitted to the stage ST via the support member SP-1, and thus, the heat may be stably blocked.

As shown in FIG. 6B, lower surfaces 21 and 22 and side surfaces 30 and 40 of a support member SP-2 may have an inclined surface. Accordingly, a contact SS between the support member SP-2 and a surface of a groove GV may be provided in the form of point contact. A contact area between the support member SP-2 and the groove GV may be reduced by changing a shape of the lower surfaces 21 and 22 and a shape of the side surfaces 30 and 40.

In an embodiment, as shown in FIG. 6C, a support member SP-3 may include a curved surface GR. As the support member SP-3 includes the curved surface GR, such as a wrinkle shape, a contact area between the support member SP-3 and a groove GV may be reduced compared with a case where the support member SP-3 has a flat surface.

According to the disclosure, as the shape of the support surface 10 is maintained while providing the other surfaces of each of the support members SP, SP-1, SP-2, and SP-3 in various shapes, the heat dissipation plate RDP may be stably supported, and the contact area between the stage ST and the support members SP, SP-1, SP-2, and SP-3 may be reduced. Accordingly, the heat dissipation plate RDP may be prevented from sagging by gravity, and the heat may be prevented from being transmitted to the stage ST via the support members SP, SP-1, SP-2, and SP-3.

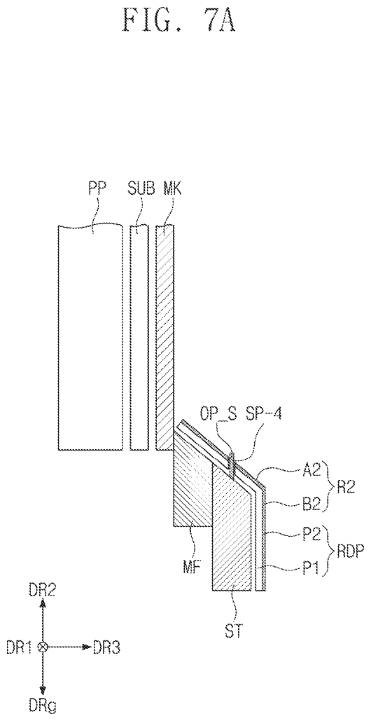

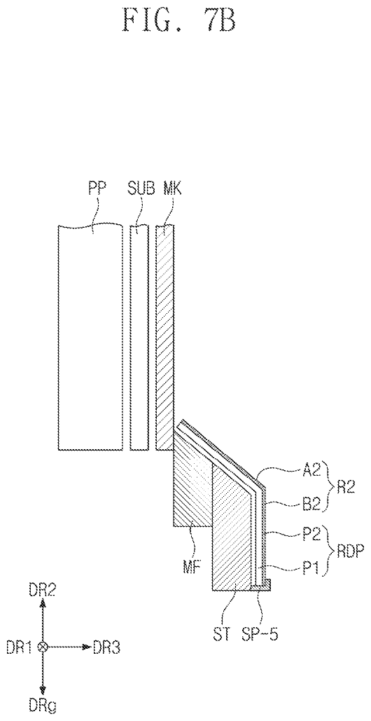

FIGS. 7A and 7B are cross-sectional views of an embodiment of a portion of a deposition apparatuses in embodiments of the disclosure. FIGS. 7A and 7B show the deposition apparatuses in an area corresponding to the embodiment shown in FIG. 5.

Referring to FIG. 7A, the deposition apparatus may further include a support member SP-4 coupled with a stage ST. The support member SP-4 may be coupled with an inner side surface of the stage ST. In this case, a heat dissipation plate RDP may be provided with a through hole OP_S. The through hole OP_S may be defined through an inclined portion A2. The support member SP-4 may be inserted into the through hole OP_S. The heat dissipation plate RDP may be coupled with the support member SP-4 inserted into the through hole OP_S and may be stably supported.

Referring to FIG. 7B, a support member SP-5 may be coupled with a rear surface of a stage ST. The support member SP-5 may include a bending portion. In detail, the support member SP-5 may include a portion extending in the third direction DR3 and a portion extending to the second direction DR2 from the portion extending in the third direction DR3. A flat portion B2 of a heat dissipation plate RDP may be supported by the bending portion.

In the illustrated embodiments, the deposition apparatuses may include the support members SP-4 and SP-5 with various shapes. Accordingly, a gap between the heat dissipation plate RDP and a mask frame MF may be maintained, and the heat dissipation plate RDP may be stably supported.

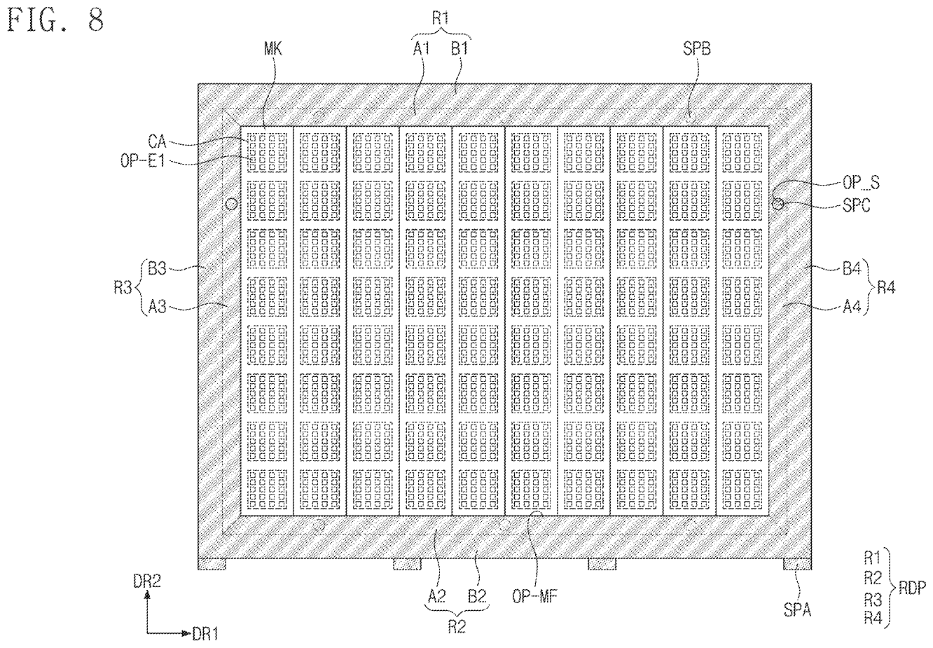

FIG. 8 is a plan view of an embodiment of a deposition apparatus according to the disclosure. For the convenience of explanation, FIG. 8 shows the deposition apparatus in an area corresponding to the embodiment shown in FIG. 3B. In FIG. 8, the same reference numerals denote the same elements in FIGS. 1 to 7B, and thus, detailed descriptions of the same elements will be omitted.

Referring to FIG. 8, the deposition apparatus may include all support members SPA, SPB, and SPC with various shapes. In an embodiment, the deposition apparatus may include first support members SPA disposed at a lower side thereof. The first support members SPA may support a third portion R3. The first support members SPA are shown in a form corresponding to the support member SP-5 (refer to FIG. 7B).

Second support members SPB may be covered by a heat dissipation plate RDP. The second support members SPB may support inclined surfaces A1 and A3 extending in the first direction DR1 among inclined surfaces A1, A2, A3, and A4 of the heat dissipation plate RDP. The second support members SPB are shown in a form corresponding to the support member SP (refer to FIG. 5) or the support members SP-1, SP-2, and SP-3 shown in FIGS. 6A to 6C.

Third support members SPC may support inclined surfaces A2 and A4 extending in the second direction DR2 among the inclined surfaces A1, A2, A3, and A4 of the heat dissipation plate RDP. The third support members SPC may be inserted into a through hole OP_S and may support the heat dissipation plate RDP. The third support members SPC are shown in a form corresponding to the support member SP-4 shown in FIG. 7A.

In the illustrated embodiment, a gravity direction may correspond to a direction opposite to the second direction DR2. According to the disclosure, various types of support members may be placed by considering the influence of gravity depending on locations in the deposition apparatus. Accordingly, the heat dissipation plate RDP may be stably supported.

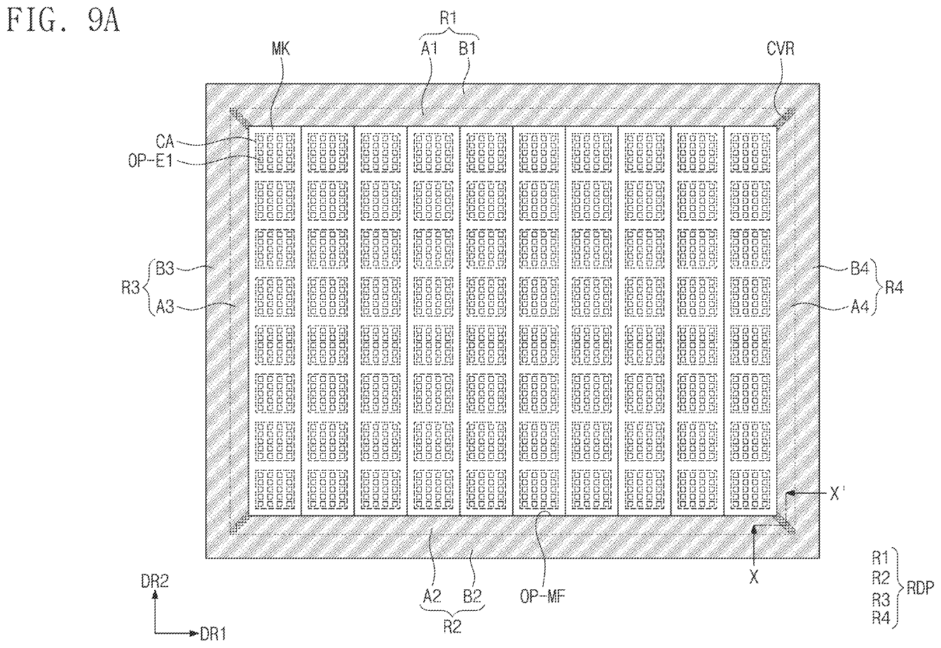

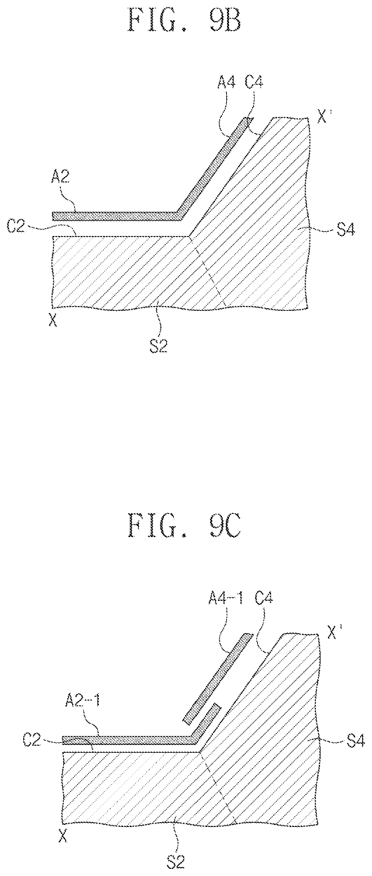

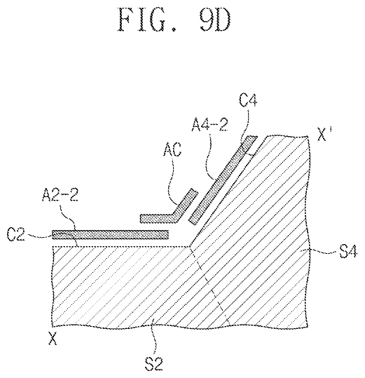

FIG. 9A is a plan view of a deposition apparatus according to the disclosure. FIGS. 9B to 9D are views of portions taken along line X-X′ shown in FIG. 9A. For the convenience of explanation, FIG. 9A shows the deposition apparatus in an area corresponding to the embodiment shown in FIG. 3B. Hereinafter, the disclosure will be described with reference to FIGS. 9A to 9D. In FIGS. 9A to 9D, the same reference numerals denote the same elements in FIGS. 1 to 8, and thus, detailed descriptions of the same elements will be omitted.

Referring to FIG. 9A, the deposition apparatus may include a predetermined cover area CVR. The cover area CVR may be provided in plural, and the cover areas CVR may be respectively disposed in areas each being defined between two inclined surfaces adjacent to each other among inclined surfaces A1, A2, A3, and A4. The line X-X′ is shown in an area where the fourth portion R4 and the second portion R2 are adjacent to each other. In FIGS. 9B to 9D, the cover area CVR may include a dotted line area between the fourth portion R4 and the second portion R2.

Referring to FIG. 9B, the inclined portion A2 of the second portion R2 may extend to or from the inclined portion A4 of the fourth portion R4 in the cover area CVR. The cover area CVR, i.e., the area where sides S2 and S4 of a stage ST extend to or from each other, may be covered by the inclined surfaces A2 and A4 having a single-layer structure.

Referring to FIG. 9C, an inclined portion A2-1 of a second portion R2 and an inclined portion A4-1 of a fourth portion R4 may be separated from each other and may partially overlap each other in a cover area CVR in the plan view. In the illustrated embodiment, a structure in which the inclined portion A2-1 of the second portion R2 overlaps second and fourth sides S2 and S4 of the stage ST and the inclined portion A4-1 of the fourth portion R4 covers only the fourth side S4 of the second and fourth sides S2 and S4 is shown. Accordingly, the cover area CVR may be covered by the inclined surfaces A2-1 and A4-1 overlapping each other.

Referring to FIG. 9D, a cover area CVR may be exposed without being covered by an inclined portion A2-2 of a second portion R2 and an inclined portion A4-2 of a fourth portion R4. In this case, the deposition apparatus may further include a cover member AC. The cover area CVR exposed without being covered by the inclined portion A2-2 of the second portion R2 and the inclined portion A4-2 of the fourth portion R4 may be covered by the cover member AC. Accordingly, the cover area CVR may not overlap the inclined surfaces A2-2 and A4-2 and may overlap the cover member AC.

According to FIGS. 9C and 9D, since the inclined portion A2-1 (or A2-2) of the second portion R2 and the inclined portion A4-1 (or A4-2) of the fourth portion R4 are separated from each other, an inclination angle of each of the inclined portion A2-1 (or A2-2) and the inclined portion A4-1 (or A4-2) may be set differently. The inclination angle of the inclined surfaces A2-1 (or A2-2) of the second portion R2 and the inclination angle of the inclined surfaces A4-1 (or A4-2) of the fourth portion R4 may be independently designed from each other, and thus, a degree of freedom in the shape of the heat dissipation plate RDP that covers other components may be improved.

In the illustrated embodiment, the shape of the heat dissipation plate RDP may be designed in various ways, and thus the mask frame MF and the stage ST may be effectively covered. Accordingly, a heat-blocking ability of the heat dissipation plate RDP may be improved.

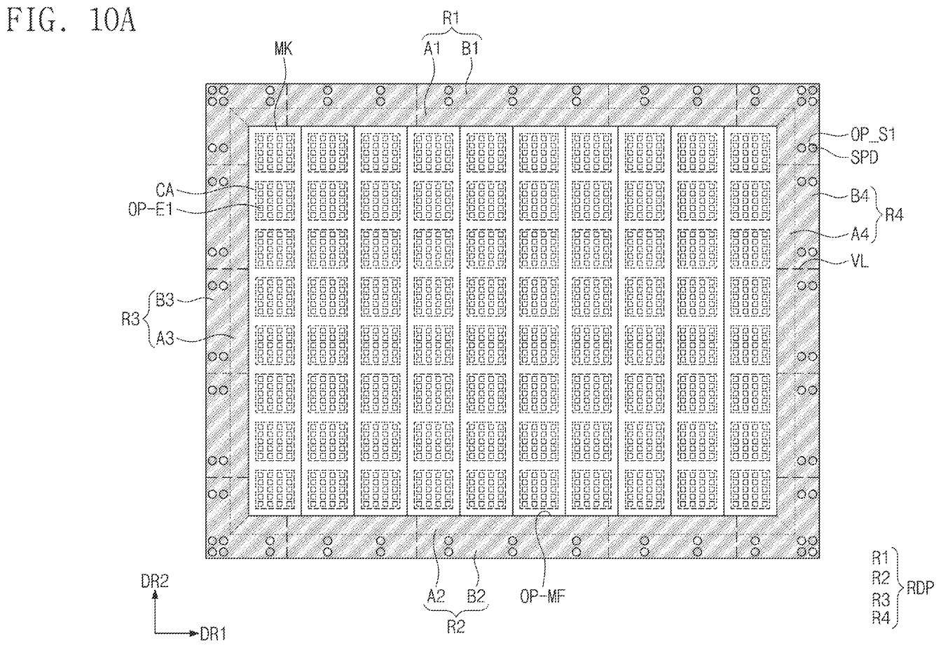

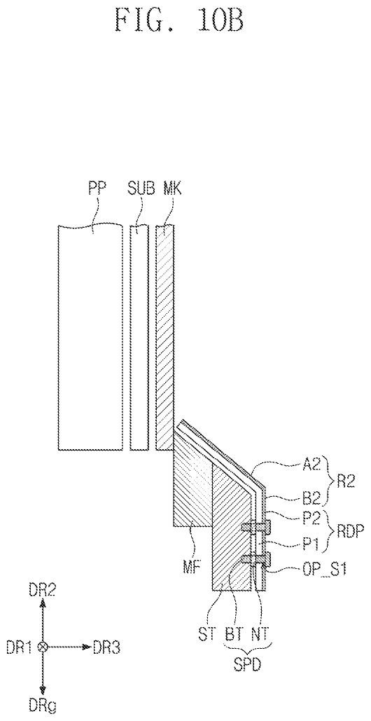

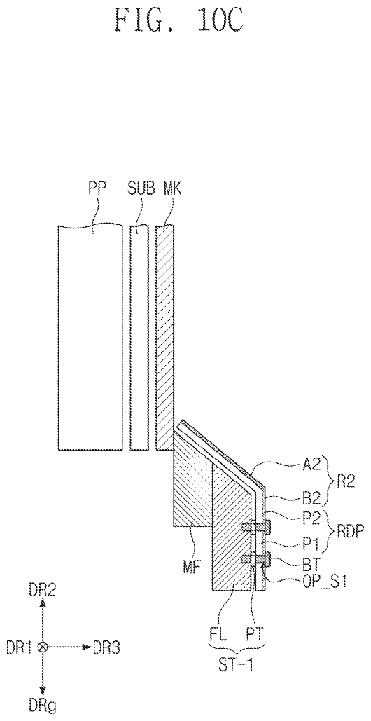

FIG. 10A is a plan view of an embodiment of a deposition apparatus according to the disclosure. FIGS. 10B and 10C are cross-sectional views of a portion of deposition apparatuses in embodiments of the disclosure. FIGS. 10B and 10C are cross-sectional views of the portion of the deposition apparatus shown in FIG. 10A and, for the convenience of explanation, show the deposition apparatus in an area corresponding to the embodiment shown in FIG. 5. Hereinafter, the disclosure will be described with reference to FIGS. 10A to 10C. In FIGS. 10A to 10C, the same reference numerals denote the same elements in FIGS. 1 to 9D, and thus, detailed descriptions of the same elements will be omitted.

Referring to FIG. 10A, a support member SPD may be provided in plural, and the support members SPD may be uniformly arranged in first, second, third, and fourth portions R1, R2, R3, and R4. The support members SPD may be inserted into openings OP_S1 defined through the first, second, third, and fourth portions R1, R2, R3, and R4. In the illustrated embodiment, when each of the first, second, third, and fourth portions R1, R2, R3, and R4 is divided into plural areas by imaginary lines VL, at least four support members SPD may be arranged in each area among the plural areas obtained by dividing each of the first, second, third, and fourth portions R1, R2, R3, and R4, however, this is merely one of embodiments. In an embodiment, the number and arrangement of the support members CP should not be particularly limited as long as a stage ST and a heat dissipation plate RDP are stably coupled with each other.

Referring to FIG. 10B, each of the support members SPD may include a bolt BT and a nut NT. The bolt BT may be inserted into the stage ST after passing through the opening OP_S1 defined through the heat dissipation plate RDP. The nut NT may be disposed between the heat dissipation plate RDP and the stage ST and may be engaged with the bolt BT. The nut NT may uniformly maintain a distance between the heat dissipation plate RDP and the stage ST.

Referring to FIG. 10C, a nut NT may be omitted in each of support members SPD. Each of the support members SPD in FIG. 10A may include only a bolt BT. In this case, a stage ST-1 may include a flat portion FL and a protruding portion PT. The flat portion FL may have a shape corresponding to that of the stage ST shown in FIG. 10B. The protruding portion PT that protrudes from the flat portion FL may uniformly maintain a gap between a heat dissipation plate RDP and the stage ST-1. The bolt BT may be inserted into a groove defined in the flat portion FL and may be engaged with the stage ST-1 after penetrating through the protruding portion PT.

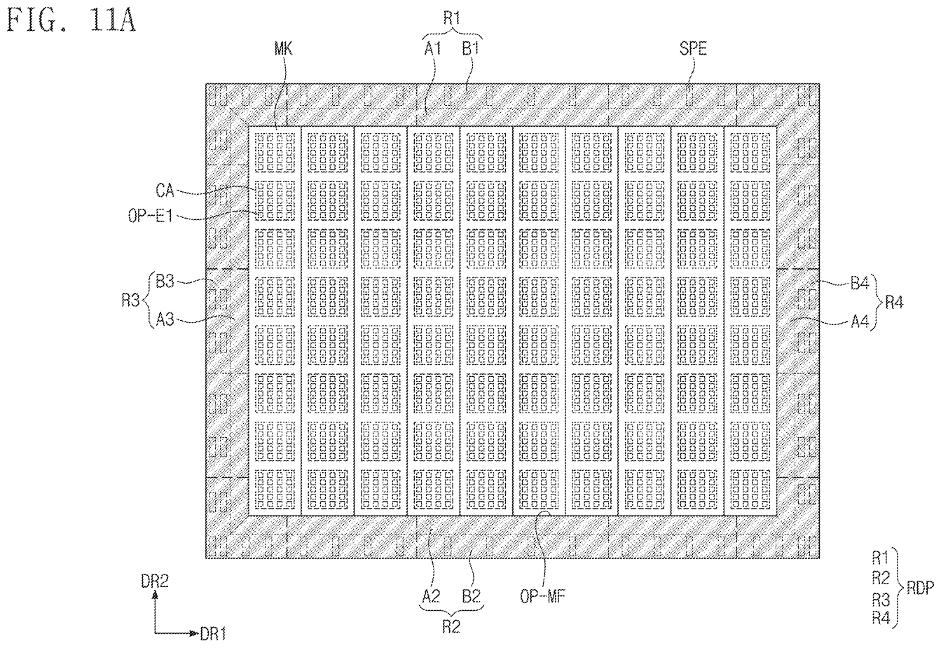

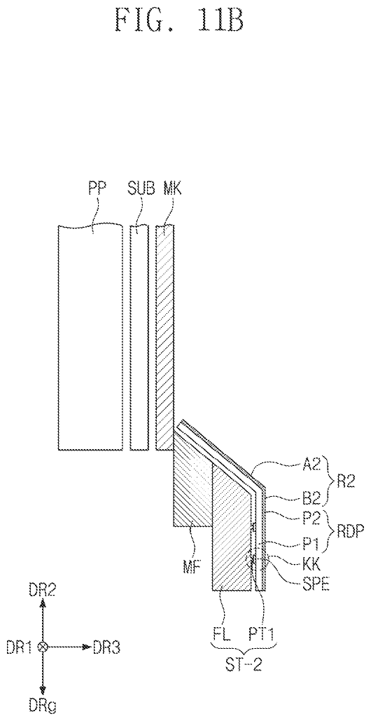

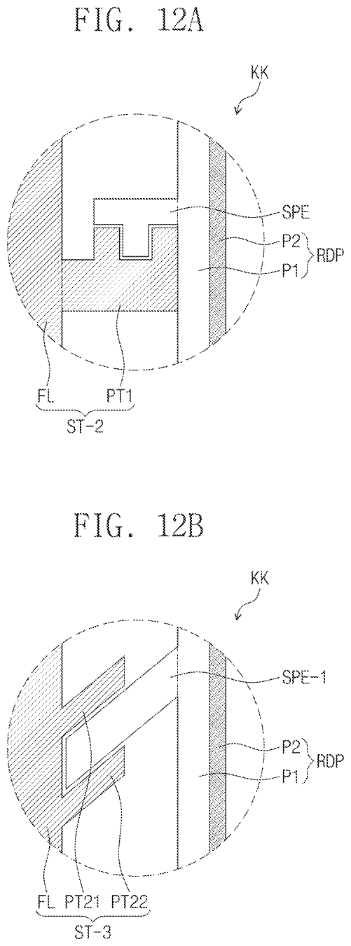

FIG. 11A is a plan view of an embodiment of a deposition apparatus according to the disclosure. FIG. 11B is a cross-sectional view of an embodiment of a portion of a deposition apparatus according to the disclosure. FIGS. 12A and 12B are enlarged cross-sectional views of an area KK shown in FIG. 11B. FIG. 11B shows the portion of the deposition apparatus shown in FIG. 11A and, for the convenience of explanation, shows the deposition apparatus in an area corresponding to the embodiment shown in FIG. 5. Hereinafter, the disclosure will be described with reference to FIGS. 11A to 12B. In FIGS. 11A to 12B, the same reference numerals denote the same elements in FIGS. 1 to 10C, and thus, detailed descriptions of the same elements will be omitted.

Referring to FIGS. 11A and 11B, a support member SPE may be provided in plural, and the support members SPE may be uniformly arranged in first, second, third, and fourth portions R1, R2, R3, and R4. The support members SPE may be disposed between a heat dissipation plate RDP and a stage ST-2, and the support members SPE may not be visible when viewed from above of the heat dissipation plate RDP. Accordingly, the support members SPE are indicated by a dotted line.

The stage ST-2 may include a flat portions FL and a protruding portion PT1. The protruding portion PT1 may be provided in plural, and the protruding portions PT1 may be respectively coupled with the support members SPE. According to the disclosure, the support members SPE may not be exposed to the deposition material during the deposition process, and thus, a stability of the deposition apparatus may be improved.

For the convenience of explanation, FIGS. 12A and 12B show enlarged views of the area KK of the support member SPE.

Referring to FIG. 12A, the protruding portion PT1 may provide a concave space upward, and the support member SPE may be provided integrally with a first layer P1 of the heat dissipation plate RDP and may provide a convex portion protruding downward. The support member SPE may be inserted into the concave space provided by the protruding portion PT1 and may be supported by the concave space. Accordingly, the heat dissipation plate RDP may be stably supported by a force against gravity.

Referring to FIG. 12B, a support member SPE-1 may protrude from a first layer P1 to a diagonal direction downward, and a stage ST-3 may include a flat portion FL and portions PT21 and PT22, which define a concave space to accommodate the support member SPE-1. The portions PT21 and PT22 may protrude from the flat portions FL to a diagonal direction upward. By embodiments, the support members SPE and SPE-1 may be formed as a member separate from the heat dissipation plate RDP and should not be particularly limited.

According to the disclosure, the support members SPE and SPE-1 may be disposed on a rear surface of the heat dissipation plate RDP and may be hook-coupled to the stages ST-2 and ST-3, respectively, however, these are merely some of embodiments. By embodiments, the support members SPE and SPE-1 may have various shapes as long as the heat dissipation plate RDP is stably coupled to the stages ST-2 and ST-3 without sagging due to gravity and should not be particularly limited.

Although the embodiments of the disclosure have been described, it is understood that the disclosure should not be limited to these embodiments but various changes and modifications may be made by one ordinary skilled in the art within the spirit and scope of the disclosure as hereinafter claimed. Therefore, the disclosed subject matter should not be limited to any single embodiment described herein, and the scope of the inventive concept shall be determined according to the attached claims.

What is claimed is:

1. A deposition apparatus comprising:
a deposition member which provides a deposition material;
a stage comprising:
a first rear surface facing the deposition member;
a first front surface opposite to the first rear surface; and
a first inner side surface extended to the first rear surface and the first front surface, defining a first opening, and inclined with respect to each of the first front surface and the first rear surface;
a mask frame comprising:
a second rear surface facing the first front surface;
a second front surface opposite to the second rear surface; and
a second inner side surface extended to the second front surface and the second rear surface, defining a second opening, and inclined with respect to each of the second front surface and the second rear surface;
a plurality of masks disposed on the second front surface, each of the plurality of masks defining a plurality of deposition openings corresponding to the second opening; and
a heat dissipation plate disposed between the deposition member and a mask of the plurality of masks and covering the first rear surface, the first inner side surface, and the second inner side surface.

2. The deposition apparatus of claim 1, wherein the heat dissipation plate comprises a flat portion and an inclined portion bent from the flat portion, the flat portion covers the first rear surface, and the inclined portion covers the first inner side surface and the second inner side surface.

3. The deposition apparatus of claim 2, wherein the inclined portion is spaced apart from the second inner side surface.

4. The deposition apparatus of claim 3, wherein a distance between the inclined portion and the second inner side surface is equal to or greater than about 2 millimeters and equal to or smaller than about 10 millimeters.

5. The deposition apparatus of claim 3, wherein an angle between the inclined portion and the flat portion is equal to or greater than about 110 degrees and equal to or smaller than about 130 degrees.

6. The deposition apparatus of claim 3, wherein the inclined portion is spaced apart from the plurality of deposition openings in a plan view.

7. The deposition apparatus of claim 2, wherein the second inner side surface comprises:
a first surface extending in a first direction;
a second surface extending in the first direction and facing the first surface;
a third surface extending in a second direction crossing the first direction and extended to the first surface and the second surface; and
a fourth surface extending in the second direction and extended to the first surface and the second surface, and the inclined portion comprises first, second, third, and fourth inclined surfaces respectively covering the first, second, third, and fourth surfaces, each of the first, second, third, and fourth inclined surfaces comprises one side extended to the flat portion and an opposite side opposing to the one side, and
wherein the opposite sides of the first to fourth inclined portions are able to be separated from each other.

8. The deposition apparatus of claim 7, wherein the first, second, third, and fourth inclined surfaces do not overlap each other.

9. The deposition apparatus of claim 8, wherein the heat dissipation plate further comprises a cover member, at least a portion of the second inner side surface is exposed without being covered by the first, second, third, and fourth inclined surfaces, and the cover member covers the at least the portion of the second inner side surface.

10. The deposition apparatus of claim 7, wherein the first, second, third, and fourth inclined surfaces overlap each other in a plan view.

11. The deposition apparatus of claim 1, wherein the first inner side surface is aligned with the second inner side surface.

12. The deposition apparatus of claim 1, further comprising a support member coupled to the stage and supporting the heat dissipation plate.

13. The deposition apparatus of claim 12, wherein the stage further comprises a groove defined in the first inner side surface, and the support member is inserted into the groove.

14. The deposition apparatus of claim 13, wherein at least a portion of the groove is spaced apart from the support member.

15. The deposition apparatus of claim 12, wherein the heat dissipation plate further comprises a hole defined therethrough, and the support member is inserted into the hole.

16. The deposition apparatus of claim 15, wherein the support member comprises a bolt.

17. The deposition apparatus of claim 12, wherein the support member comprises a bending portion which supports a side surface of the heat dissipation plate.

18. The deposition apparatus of claim 1, further comprising a support member disposed on the heat dissipation plate and facing the first rear surface, and
wherein the heat dissipation plate is supported and coupled to the stage through the support member.

19. The deposition apparatus of claim 18, wherein one of the support member and the stage comprises a concave portion defined therein, a remaining one of the support member and the support member comprises a convex portion defined therein, and the convex portion is inserted into the concave portion.

20. The deposition apparatus of claim 18, wherein the support member is inclined with respect to the first rear surface, and the support member is inserted into the stage.

21. The deposition apparatus of claim 1, wherein the first and second rear surfaces are substantially parallel to a gravity direction.

22. A deposition apparatus comprising:
a chamber comprising a bottom surface and a side surface defining an inner space;
a deposition member disposed on the side surface which provides a deposition material;
a mask frame accommodated in the inner space and comprising:
a rear surface facing the deposition member;
a front surface opposite to the rear surface;
a side surface extended to the front surface and the rear surface; and
an inner side surface opposite to the side surface of the mask frame and defining an opening with a diameter that varies along a direction penetrating through the front surface and the rear surface;
a plurality of masks disposed on the front surface, each of the plurality of masks defining a plurality of deposition openings corresponding to the opening; and
a heat dissipation plate disposed between the deposition member and the mask frame and comprising a flat portion parallel to the rear surface and an inclined portion bent from the flat portion and covering the inner side surface.

23. The deposition apparatus of claim 22, wherein the inclined portion is parallel to the inner side surface and spaced apart from the inner side surface.

24. The deposition apparatus of claim 22, wherein the rear surface is inclined with respect to the bottom surface.

25. The deposition apparatus of claim 22, wherein the inclined portion has an integral shape.

26. The deposition apparatus of claim 22, wherein the inclined portion comprises a plurality of inclined surfaces, and each of the plurality of inclined surfaces is extended to the flat portion and bent from the flat portion.

27. The deposition apparatus of claim 26, wherein one of the plurality of inclined surfaces and another one of the plurality of inclined surfaces have inclined angles different from each other.

28. The deposition apparatus of claim 26, wherein some of the plurality of inclined surfaces overlap each other in a plan view.

29. The deposition apparatus of claim 26, wherein the heat dissipation plate further comprises a cover member, the inclined portion are spaced apart from each other in a plan view, and the cover member overlaps two inclined surfaces adjacent to each other among the plurality of inclined surfaces in the plan view.
